(19) United States
(12) Patent Application Publication
(10) Pub. No.: US 2026/0106137 A1
(43) Pub. Date: Apr. 16, 2026

(54) LOW-COST HIGH-PERFORMANCE SILICON-CARBON (SiC) COMPOSITE ANODE MATERIALS FOR LITHIUM-ION BATTERIES

(71) Applicant: MAPLE MATERIALS INC., Richmond, CA (US)

(72) Inventors: Kevin Yu, Berkeley, CA (US); Niklas Mundhenk, El Cerrito, CA (US); Drew L. Reid, San Rafael, CA (US)

(73) Assignee: MAPLE MATERIALS INC., Richmond, CA (US)

(21) Appl. No.: 19/422,120

(22) Filed: Dec. 16, 2025

Related U.S. Application Data
(63) Continuation-in-part of application No. 18/824,001, filed on Sep. 4, 2024.
(60) Provisional application No. 63/734,889, filed on Dec. 17, 2024.

(51) Int. Cl. H01M 4/36; C23C 16/26; C23C 16/44; H01M 4/02; H01M 4/04; H01M 4/38; H01M 4/587; H01M 4/62

(52) U.S. Cl. CPC H01M 4/364; C23C 16/26; C23C 16/4417; H01M 4/0428; H01M 4/0469; H01M 4/366; H01M 4/387; H01M 4/587; H01M 4/625; H01M 2004/021

(57) ABSTRACT

A silicon-carbon (Si/C) composite anode material includes a carbon scaffold material of carbon particles having graphite sheets configured as generally hexagonally shaped cells interconnected to one another in a 3-D honeycomb-like structure of multiple cell arrays and having a plurality of pores separating the cell arrays; silicon embedded in the pores of the 3-D honeycomb-like structure; and a carbon coating on a surface of the carbon particles. A process for producing a silicon-carbon (Si/C) composite anode material includes providing a carbon scaffold material of carbon particles having graphite sheets configured as generally hexagonally shaped cells interconnected to one another in a 3-D honeycomb-like structure of multiple cell arrays having a plurality of pores separating the cell arrays; and depositing silicon into the pores of the 3-D honeycomb-like structure.

### CROSS REFERENCE TO RELATED APPLICATION

This application is a continuation-in-part of application Ser. No. 18/824,001, filed Sep. 4, 2024, and claims priority from U.S. Provisional No. 63/734,889, filed Dec. 17, 2024, both of which are incorporated herein by reference.

### FIELD

This disclosure relates to lithium-ion batteries and to materials for making anodes for lithium-ion batteries.

### BACKGROUND

Silicon is one of the most promising anode materials due to its high theoretical energy density of 4200 mAh/g (˜10 times higher than graphite due to Li₄Si phase), low electrochemical potential (0.6V vs. Li/Li+), and its domestic availability relative to graphite. One significant drawback of silicon is its ˜300% volume expansion during charge and discharge cycles. This causes two key issues: 1) cracking and pulverization of the silicon particle causes continuous growth of the solid electrolyte interphase (SEI) layer resulting in low cycling efficiency, 2) macro-scale cracking and fragmentation of the electrode coating, leading to islanding of electroactive material and rapid capacity fade.

To address the issues caused by the expansion of silicon, several novel silicon nanostructures have been proposed including silicon nanoparticles, nanowires, nanotubes, yolk-shell structures, porous silicon sponges. Research has demonstrated that silicon particles <150 nm can accommodate significant stress from the electrochemical reaction without driving crack propagation (pulverization).

The use of carbon-nanosilicon composites in particular has been one of the most successful strategies to overcome mechanical failure. Here, a carbon matrix is used for a “dual” purpose (e.g., to allow Li-ion intercalation and create void space in the electrode to contain nanosilicon particles to accommodate volumetric change). The carbon buffers the expansion of nanosilicon and maintains the structural integrity of the electrode. This strategy was experimentally shown to be effective by many groups. For instance, one study reported a yolk-shell structured Si@Carbon with excellent capacity (2,833 mAh/g at C/10), cycle-life (1,000 cycles with 74% capacity retention), and coulombic efficiency (99.84%). Another group reported Si nanoparticles embedded in a 3D graphene scaffold with a reversible capacity of 3,200 mAh/g and 83% capacity retention after 150 cycles. More recently, a porous CNT@Si@C microsphere anode (“yarn balls”) was reported that delivers a reversible capacity of ˜1500 mAh/g and 87% capacity retention over 1500 cycles at 1 mA/cm². While many groups have shown a significant boost in the specific capacity of the anode, translating lab-based experiments to commercial-scale production remains a formidable challenge, requiring extensive optimization of manufacturing processes and materials to ensure scalability, cost-effectiveness, and long-term performance reliability.

The present disclosure is directed to anode materials comprised of silicon-carbon (SiC) composite anode materials for lithium-ion battery having a novel molecular geometry and improved properties and operational characteristics over conventional carbon anode materials. The present disclosure also relates to processes for making silicon-carbon (SiC) composite anode materials in a quantity sufficient for large scale manufacturing applications and without the production of harmful by-products.

### SUMMARY

A silicon-carbon (Si/C) composite anode material includes a carbon scaffold material comprised of carbon particles having graphite sheets configured as generally hexagonally shaped cells interconnected to one another in a 3-D honeycomb-like structure of multiple cell arrays and having a plurality of pores separating the cell arrays. The silicon-carbon (Si/C) composite anode material also includes silicon embedded in the pores of the 3-D honeycomb-like structure, and can also include a carbon coating on surfaces of the carbon particles. In addition, the silicon can comprise deposited amorphous and/or polycrystalline silicon nanoparticles.

A process for producing a silicon-carbon (Si/C) composite anode material includes the steps of providing a carbon scaffold material comprising a plurality of carbon particles comprising graphite sheets configured as generally hexagonally shaped cells interconnected to one another in a 3-D honeycomb-like structure of multiple cell arrays having a plurality of pores separating the cell arrays; and depositing silicon into the pores of the 3-D honeycomb-like structure. In an illustrative embodiment the silicon comprises silicon nanoparticles deposited into the pores of the 3-D honeycomb-like structure using a chemical vapor deposition (CVD) process. In addition, the silicon nanoparticles can be derived from monosilane and/or trichlorosilane.

### BRIEF DESCRIPTION OF THE DRAWINGS

FIG. 1A is a scanning electron micrograph having a scale bar of 100 μm on the left side of a carbon scaffold material for a silicon-carbon (Si/C) composite anode material;

FIG. 1B is a scanning electron micrograph having a scale bar of 60 μm on the left side of an enlarged portion of a single carbon particle of the carbon scaffold material comprised of graphite sheets formed as a plurality of arrays in a 3-D honeycomb structure;

FIG. 1C is a scanning electron micrograph having a scale bar of 20 μm on the left side of an enlarged portion of the carbon particle;

FIG. 1D is a scanning electron micrograph having a scale bar of 8 μm on the left side of an enlarged portion of the carbon particle;

FIG. 2A is a scanning electron micrograph having a scale bar of 4 μm on the left side of an enlarged portion of the carbon particle;

FIG. 2B is an enlarged schematic perspective view having a scale bar of 0.8 μm on the left side of an enlarged portion of the carbon particle;

FIG. 3 is a graph illustrating pore size in nm on the x-axis versus dV/dW pore volume (cm²/g:nm) on the y-axis for three samples of the carbon scaffold material;

FIG. 4 is a bar graph illustrating total pore volume (cm³/g) (2-6 nm) on the y-axis for the three samples of the carbon scaffold material;

FIG. 5 is an x-ray diffractogram for the carbon scaffold material;

FIG. 6 is a Raman spectrum for the carbon scaffold material with Raman Shift (cm⁻¹) on the x-axis and Normalized Intensity (a.u.) on the y-axis;

FIG. 7A is an enlarged schematic cross sectional view of a silicon-carbon (Si/C) composite anode material having embedded silicon;

FIG. 7B is an enlarged schematic cross sectional view of a carbon particle of the silicon-carbon (Si/C) composite anode material having a graphitized silicon carbon coating;

FIG. 7C is an X-ray diffractogram of the silicon-carbon (Si/C) composite anode material manufactured using the carbon scaffold material;

FIG. 7D is a graph showing lithiation and de-lithiation characteristics of the silicon-carbon (Si/C) composite anode material;

FIG. 8 is a simplified diagram of a process for manufacturing the carbon scaffold material of the silicon-carbon composite anode material;

FIG. 9A is a graph showing gravimetric capacity (mAh/g) for the (Si/C) composite anode material of Example 2 with a silicon content of 40% as summarized in Table 7; and

FIG. 9B is a graph showing gravimetric capacity (mAh/g) for the (Si/C) composite anode material of Example 3 with a silicon content of 17% as summarized in Table 7.

### DETAILED DESCRIPTION

As used herein, “mesoporous” means porous materials having pore diameters between 2 and 50 nm, high specific surface area, regular and orderly pore structure, and narrow pore size distribution. “Graphite” means the crystalline form of the element carbon. The term “graphite sheets” in this disclosure means flat planar sheets having a thickness of about 50 nm or less and a selected geometry. “Geometry” when referring to the graphite sheets means the shape and size of the sheets. “Honeycomb structure” when referring to the graphite sheets means a structure formed by the graphite sheets having the geometry of a honeycomb comprised of interlocking generally hexagonally shaped cells. “Carbonate” means a salt of carbonic acid, H₂CO₃, characterized by the presence of the carbonate ion, a polyatomic ion with the formula CO₃²⁻. “Alkali metal carbonate” means a carbonate containing a metal. “Scaffold” means a structural support and framework at the molecular level.

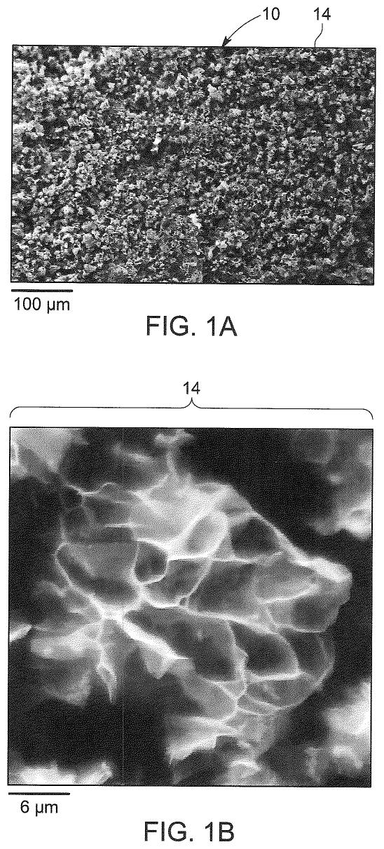

Referring to FIG. 1A, a carbon scaffold material 10 is shown. The carbon scaffold material 10 includes a plurality of carbon particles 14 having a generally spherical shape and a mesoporous structure. Although the carbon particle 14 is described herein as having a generally spherical shape, it is understood that in actual practice the carbon particle 14 can also be more asymmetrical and organically shaped. FIG. 1B illustrates an enlarged portion of a single carbon particle 14. FIG. 1A has a scale of 100 μm per 0.5 inches and FIG. 1B has a scale of 6 μm per 0.5 inches. Each carbon particle 14 has a diameter D of between 5 to 200 μm. In addition, the carbon scaffold material 10 can have a particle size distribution consisting of various particle diameters D selected to allow the graphitic carbon material 10 to be used as a material in a particular manufacturing process, such as an additive manufacturing process.

Table 1 lists exemplary physical properties for the carbon scaffold material 10.

TABLE 1
PHYSICAL PROPERTIES OF
CARBON SCAFFOLD MATERIAL 10
Particle Size Distribution (μm).

| | |
|---|---|
| D10 | 5-20 |
| D50 | 9-35 |
| D90 | 13-70 |
| Tapped Density (g/cm³) | >0.5 |
| BET Surface Area (m²/g) | <5 |

Table 2 lists exemplary electrochemical properties for the carbon scaffold material 10.

TABLE 2
ELECTROCHEMICAL PROPERTIES OF
CARBON SCAFFOLD MATERIAL 10

| | |
|---|---|
| C/10 Reversible Capacity (mAh/g) | ≥320 |
| 5 C Power Retention (%) | ≥75 |
| First Cycle Efficiency (%) | ≥90 |

Referring to FIGS. 1C and 1D, further geometry of an enlarged portion of the carbon particle 14 is shown in scanning electron micrographs. FIG. 1C has a scale of 20 μm per 0.5 inches and FIG. 1D has a scale of 8 μm per 0.5 inches. As shown in FIGS. 1C and 1D, each carbon particle comprises a plurality of graphite sheets 12. In FIGS. 1C and 1D, the graphite sheets 12 are the light areas. As also shown in FIGS. 1C and 1D, the graphite sheets 12 are configured as multiple arrays 22 comprised of generally hexagonally shaped cells 18 connected to one another in a 3-D honeycomb-like structure and separated by a plurality of pores 20. In FIGS. 1C and 1D, the pores are too small to be seen but have a pore size of between 2 to 100 nm.

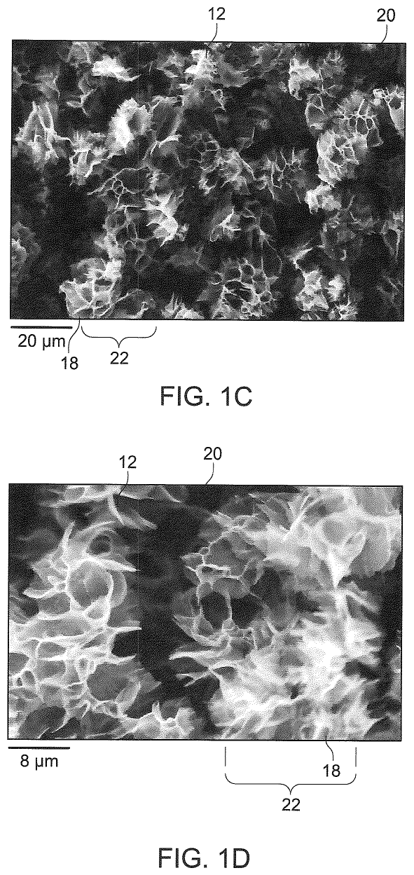

Referring to FIGS. 2A and 2B, the geometry of the hexagonally shaped cells 18 and the graphite sheets 12 are illustrated. FIG. 2A has a scale of 40 μm per 0.5 inches and FIG. 2B has a scale of 0.8 μm per 0.5 inches. In FIG. 2A the array 22 comprises a plurality of hexagonally shaped cells 18 connected to one another. In addition, the graphite sheets 12 that form the cells 18 have a thickness of T of only about 50 nanometers. Further, the interconnected hexagonally shaped cells 18 formed by the graphite sheets 12 form an electrical network that provides a low electrical resistivity throughout the carbon particle 14. Although the hexagonally shaped cells 18 are described herein as being uniform symmetrical structures, it is understood that in actual practice, the arrays 22 and hexagonally shaped cells 18 as well, have a more organic structure with curves and missing parts of the hexagons, substantially as shown in the scanning electron micrographs of FIGS. 2A and 2B. FIG. 2B illustrates the 3-D honeycomb-like structure with the hexagonally shaped cells 18 having a height H and the arrays 22 having a length L.

In illustrative embodiments, the carbon scaffold material 10 has a carbon content of 85-100% and a high porosity. Other characteristics of the carbon scaffold material 10 include: density, surface area, expansion and pH configured to make the carbon scaffold material 10 suitable for various energy applications, such as anodes for batteries. Table 3 lists exemplary physical properties of the carbon scaffold material 10. Table 4 lists exemplary crystalline properties of the carbon scaffold material 10.

TABLE 3
PHYSICAL PROPERTIES OF
CARBON SCAFFOLD MATERIAL 10

| | |
|---|---|
| % Carbon | 85-100 |
| % Sulfur | 0-0.01 |
| **Electrical Resistivity (Ω · Cm) | <0.06 |
| True Density (g/cc) | 2.12-2.26 |
| Tapped Density (g/cc) | 0.1-1.0 |
| Surface Area (m/g) | 1-15 |
| Low Pressure Density (g/cc, 6,500 psi) | 1.1-1.3 |
| High Pressure Density (g/cc, 32,000 psi) | 1.7-2 |
| % Expansion (10 grams @ 6,500 psi) | 70-100 |
| pH | 7.8-10.2 |

PARTICLE SIZE DISTRIBUTION (μm)

| | |
|---|---|
| D10 | 5-15 |
| D50 | 15-60 |
| D90 | 60-200 |

TABLE 4
CRYSTALLINE PROPERTIES OF
CARBON SCAFFOLD MATERIAL 10

| | | |
|---|---|---|
| d-spacing | 0.3354-0.3440 | nm |
| Lc(002→110) Crystallite Size | 2-10 | nm |

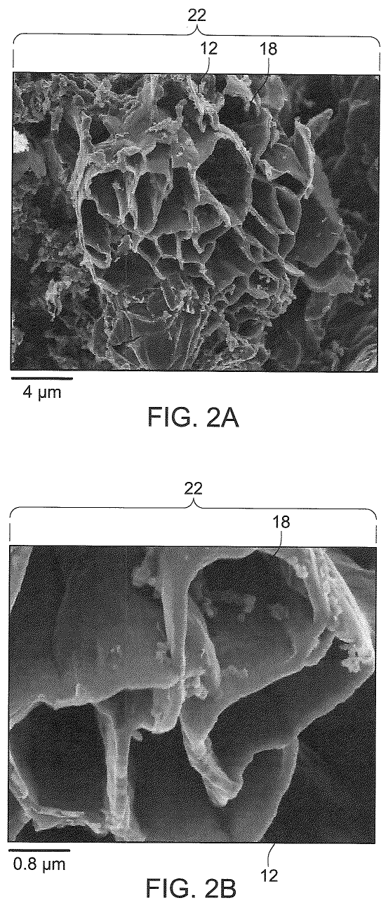

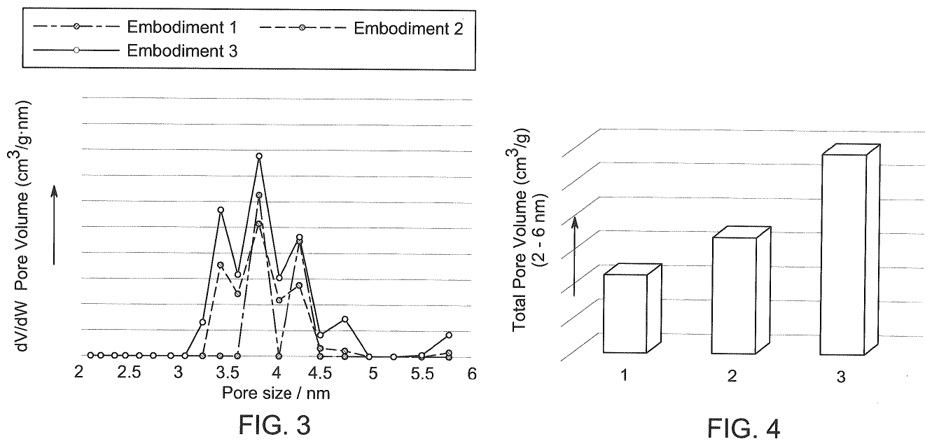

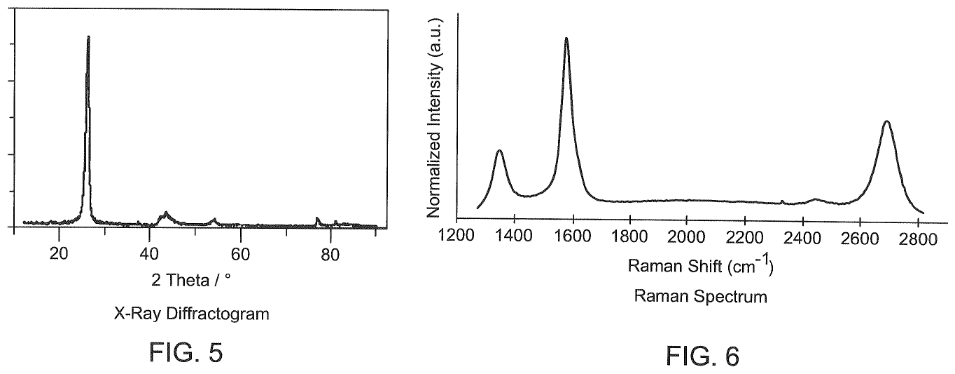

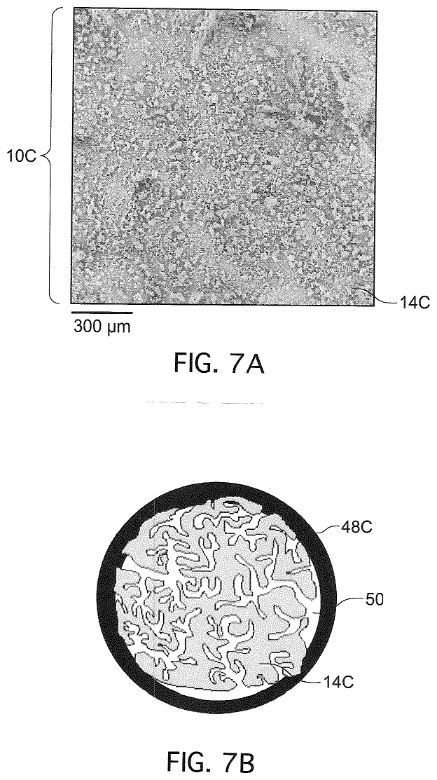

FIGS. 3 and 4 illustrate mesoporosity characteristics of the carbon scaffold material 10. FIGS. 5 and 6 illustrate x-ray diffractogram and Raman spectrum characteristics of the carbon scaffold material 10.

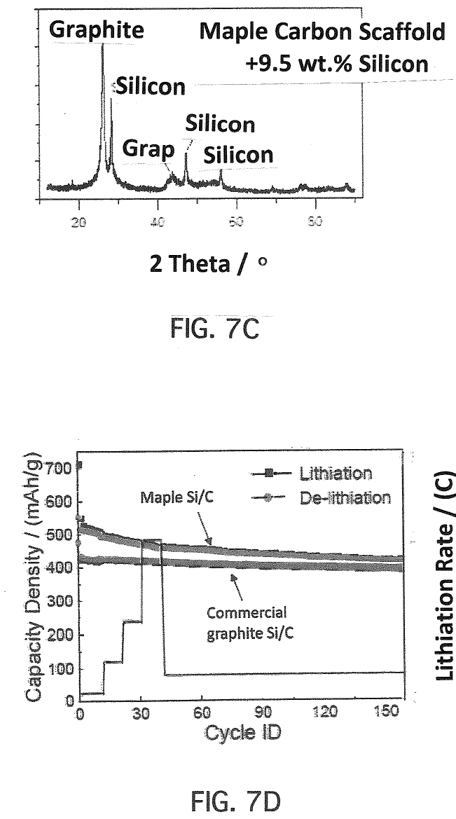

Referring to FIGS. 7A and 7B, a silicon-carbon (Si/C) composite anode material 10C includes a plurality of composite carbon particles 14C. As shown in FIG. 7B, each composite carbon particle 14C includes a graphitization carbon coating 48C formed on an outside surface thereof. For forming the composite carbon particles 14C, the composite carbon particle 14C can be used as a porous scaffold into which silicon 50 is deposited. As will be further explained, the silicon-carbon (Si/C) composite anode material 10C fabrication process can include calcination, chemical vapor deposition (CVD) or chemical vapor infiltration (CVI), and classification steps. The carbon particle 14C provides the first component of the composite, and the CVD gas thermally decomposes on this solid surface to provide the second component of composite. Such a CVD approach can be employed, for instance, to create Si—C composite materials wherein the silicon is formed in the pores 20 (FIG. 1D) the carbon particles 14C. Alternatively, chemical vapor infiltration (CVI) is a process wherein a substrate (not shown) provides a porous scaffold comprising the first component of the composite, and a silicon-containing gas thermally decomposes into the porosity (into the pores) of the porous scaffold material to provide the second component of the composite. Silicon 50 is formed within the pores of the porous carbon scaffold by subjecting the porous scaffold material to a silicon containing precursor gas, preferably silane, at elevated temperatures to decompose the gas into the silicon. The silicon containing precursor gas can also be mixed with other inert gases, for example, nitrogen gas, argon gas, or the silicon deposition can occur in a vacuum atmosphere. The temperature of processing can be varied, for example the temperature can be between 200° C. and 1,000° C. The silicon 50 can comprise amorphous and/or polycrystalline silicon.

Silicon deposition and characterization: The silicon deposition process is designed to accomplish two goals: (1) increase the reversible capacity of the silicon-carbon (Si/C) composite anode material 10C beyond the theoretical capacity of graphite (372 mAh/g) and (2) increase the tapped density of the silicon-carbon (Si/C) composite anode material 10C from 0.25 g/cm³ to >0.9 g/cm³ by filling the void space in the coral-like morphology with high-density silicon 50. FIG. 5 shows the characteristic X-ray diffraction peak associated with the as-produced carbon scaffold material 10. The 002-plane peak is observed to be narrow and centered at a 2θ value of 26.4° (Cu Kα), indicative of highly crystalline graphite. FIG. 7C shows the X-ray diffractogram of the silicon-carbon (Si/C) composite anode material, containing 9.5 wt. % of silicon. The characteristic peaks for silicon are observed at 2θ values of 28.5°, 47.3°, and 56.1°. Silicon deposition was carried out using a CVD process.

FIG. 7D illustrates lithiation and de-lithiation characteristics of the silicon-carbon (Si/C) composite anode material 10 “termed Maple Si/C” compared to “Commercial graphite Si/C” and versus a half-cell plot from Li: LA133: 6%, XC-72:8.7%, TUBAL: 0.3%, active material: 85%, loading: 2.9 g/cm³.

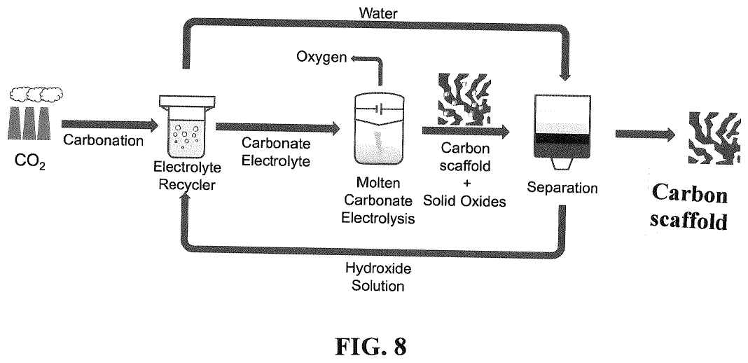

FIG. 8 illustrates a process for manufacturing the carbon scaffold structure 10 of the silicon-carbon composite anode material 10C. Further details of the process are disclosed in parent application Publication No.: US 2025/0083965 A1, which is incorporated herein by reference.

Electrolysis: Electrolysis begins with the dissociation of molten lithium carbonate into its constituent ions (Eq. 1). Experimentally, carbon obtained at an operating temperature of 750° C., an applied voltage of 2.4 V, and a current efficiency of 91%. The calculated energy consumption at these operating conditions is 20 kWh/kg. However, the thermodynamic potential required to reduce solid carbon from lithium carbonate is 1.7 V at 750° C. Operating at this ideal potential at 100% current efficiency gives a minimum energy requirement of 10.7 kWh/kg, leaving ample opportunity for further cost reduction with improved design and engineering.

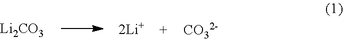

At the cathode, electrocatalytic reduction of the carbonate ion produces solid carbon and three oxide anions (Eq. 2). One oxide anion reacts with two adjacent lithium ions to produce lithium oxide (Eq. 3). The product of electrolysis on the cathode is a solid deposit of graphitic carbon intermixed with lithium oxide and residual lithium carbonate.

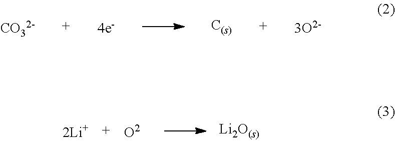

At the anode, two oxide anions are combined in an oxidation reaction that results in four electrons and the evolution of oxygen gas (Eq. 4). The rapid convection caused by the oxygen gas evolution along with a high concentration of electroactive species (carbonate anions) in the molten lithium carbonate facilitate good mass transport. Currently, no indication of a limiting current has been observed for this system.

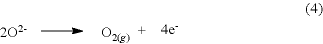

Electrolyte recycling: Graphitic carbon is separated from lithium oxide by thoroughly washing the electro-deposit in water. Lithium oxide reacts with water to convert to lithium hydroxide, which is water-soluble (128 g/L @ 20° C.) and readily separates from the deposit by filtration (Eq. 5). The filtered lithium hydroxide solution is percolated with carbon dioxide to precipitate lithium carbonate, which is dried and reintroduced into the electrolysis reactor (Eq. 6).

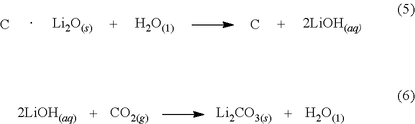

The net reaction is the conversion of carbon dioxide into graphitic and oxygen (Eq. 7).

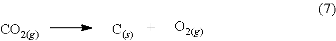

Example 1: In preliminary testing, the Applicant, Maple Materials Inc., demonstrated silicon-carbon composite anodes made with the silicon-carbon (Si/C) composite anode material 10C containing 9.5% silicon. Properties of the carbon scaffold material 10 are listed in Table 5.

TABLE 5
Particle size distribution (μm):

| | |
|---|---|
| D10 | 10 |
| D50 | 28 |
| D90 | 56 |
| Carbon Purity (wt. %) | 96 |
| Tapped Density (g/cm³): | 0.25 |
| BET Surface Area (m²/g): | 10 |

The silicon 50 (FIG. 7B) was introduced into the carbon scaffold material 10 (FIG. 1A) using a CVD (silane gas) approach. Performance was compared to baseline graphite-silicon composites using state of the art commercial graphite anode material and silicon deposited with the same CVD method at comparable loadings. approach and also at a 9.5% loading. The results are shown in Table 6. The silicon-carbon (Si/C) composite anode material 10C clearly demonstrates superior lithiation and dilithiation capacities.

TABLE 6

| | Maple | Benchmark |
|---|---|---|
| Specification | Si/C | Commercial Si/C |
| Silicon Content (%): | 9.5 | 9.5 |
| First Lithiation Capacity (mAh/g): | 712 | 470 |
| Reversible Capacity (mAh/g); | 554 | 418 |
| First Cycle Efficiency (%): | 77.8 | 88.9 |

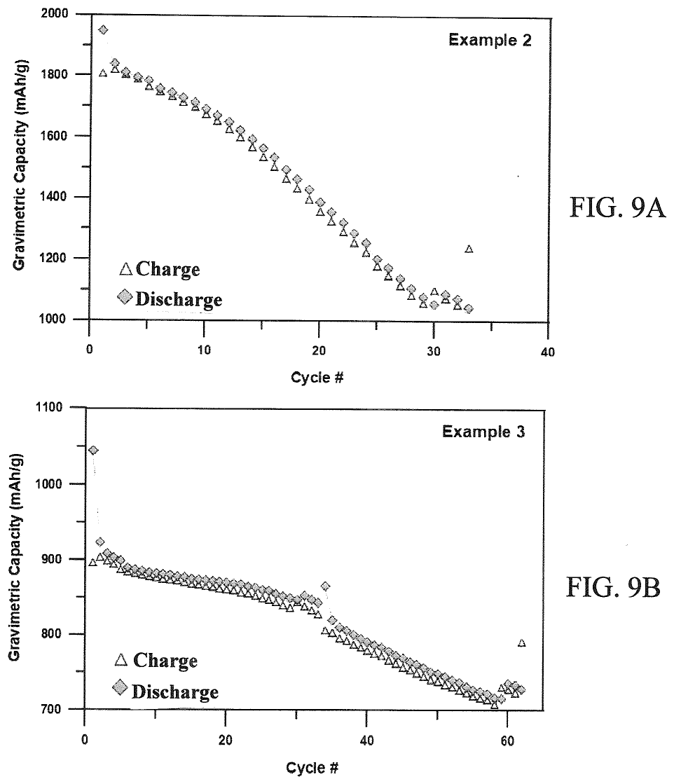

Examples 2 and 3: In preliminary testing, the Applicant, Maple Materials Inc., demonstrated silicon-carbon composite anodes made with the silicon-carbon (Si/C) composite anode material 10C containing 40% silicon (Example 2) and 17% silicon (Example 3). The results are summarized in Table 7 and FIGS. 9A and 9B.

TABLE 7

| | Maple Si/C | Maple Si/C |
|---|---|---|
| Specification | Example2 | Example3 |
| Silicon Content (%): | 40 | 17 |
| First Lithiation Capacity (mAh/g): | 1949 | 1045 |
| Reversible Capacity (mAh/g): | 1802 | 895 |
| First Cycle Efficiency (%): | 92.5 | 85.7 |

Anticipated Public Benefits: Reduced greenhouse gas emissions because improving the cost competitiveness and performance (energy density and cycle life) of silicon anodes improves the competitiveness of electric vehicles. Transportation accounts for nearly 30% of U.S. greenhouse gas emissions while electric vehicles account for ˜5% of new vehicle sales. Electric vehicles do not directly combust fossil fuels and moreover, have the ability to draw electricity from clean, domestic and renewable energy sources.

U.S. Lithium-ion Battery Supply Chain: The presently disclosed process for producing silicon-carbon (Si/C) composite anode material 10C could replace a significant fraction, or potentially all of the graphite used in the anode. Graphite is classified as a critical material. However, there are no reserves of natural graphite in the United States. Alternatively, synthetic graphite is expensive, energy intensive, and environmentally damaging. The present process is reliant on domestically sourced carbon dioxide and inexpensive renewable energy as its only feedstocks.

carbon (Si/C) composite anode material 10C sources industrial grade carbon dioxide, which is available via tanker truck and pipeline at scale. Industrial gas companies have the capability to source and purify high-concentration waste carbon dioxide from industrial processes such as ammonia production, steam methane reforming, natural gas liquefaction, as well as coal to liquids, and ethylene oxide production.

While a number of exemplary aspects and embodiments have been discussed above, those of skill in the art will recognize certain modifications, permutations, additions and subcombinations thereof. It is therefore intended that the following appended claims and claims hereafter introduced are interpreted to include all such modifications, permutations, additions and sub-combinations as are within their true spirit and scope.

We claim:

1. A silicon-carbon (Si/C) composite anode material comprising:
a carbon scaffold material comprised of carbon particles comprising a plurality of graphite sheets configured as generally hexagonally shaped cells interconnected to one another in a 3-D honeycomb-like structure of multiple cell arrays having a plurality of pores separating the cell arrays; and
silicon embedded in the pores of the 3-D honeycomb-like structure.

2. The silicon-carbon (Si/C) composite anode material of claim 1 wherein the silicon comprises amorphous or polycrystalline silicon nanoparticles.

3. The silicon-carbon (Si/C) composite anode material of claim 1 wherein the carbon scaffold material is configured for fabricating lithium-ion batteries.

4. The silicon-carbon (Si/C) composite anode material of claim 1 wherein a silicon content of the silicon-carbon (Si/C) composite anode material is from 1-99.99 wt %.

5. The silicon-carbon (Si/C) composite anode material of claim 1 wherein the carbon scaffold material has a particle size distribution of D10: 5-15, D50: 15-60, D90: 60-200.

6. The silicon-carbon (Si/C) composite anode material of claim 1 wherein the carbon scaffold material has a % carbon purity of 85-100.

7. The silicon-carbon (Si/C) composite anode material of claim 1 wherein the carbon scaffold material has a tapped density (g/cm³) of >0.3.

8. The silicon-carbon (Si/C) composite anode material of claim 1 wherein the carbon scaffold material has a BET surface area (m²/g)<20.

9. A silicon-carbon (Si/C) composite anode material comprising:
a carbon scaffold material comprised of carbon particles comprising a plurality of graphite sheets configured as generally hexagonally shaped cells interconnected to one another in a 3-D honeycomb-like structure of multiple cell arrays having a plurality of pores separating the cell arrays;
a plurality of silicon nanoparticles deposited into the pores of the 3-D honeycomb-like structure; and
a carbon coating on a surface of the carbon particles.

10. The silicon-carbon (Si/C) composite anode material of claim 9 wherein each carbon particle has a diameter D of between 5 to 200 μm.

11. The silicon-carbon (Si/C) composite anode material of claim 9 wherein the pores have a pore size of between 2 to 100 nm.

12. The silicon-carbon (Si/C) composite anode material of claim 9 wherein each carbon particle comprises 85-100 wt. % carbon.

13. The silicon-carbon (Si/C) composite anode material of claim 9 wherein each carbon particle comprises 0-0.01% sulfur.

14. The silicon-carbon (Si/C) composite anode material of claim 9 wherein each carbon particle has an electrical resistivity of less than 0.06 ohm cm.

15. A process for producing a silicon-carbon (Si/C) composite anode material comprising:
providing a carbon scaffold material comprising a plurality of carbon particles comprising graphite sheets configured as generally hexagonally shaped cells interconnected to one another in a 3-D honeycomb-like structure of multiple cell arrays having a plurality of pores separating the cell arrays; and
depositing silicon nanoparticles into the pores of the 3-D honeycomb-like structure.

16. The process of claim 15 wherein the carbon particles include a carbon coating on surfaces thereof.

17. The process of claim 15 wherein the depositing step comprises chemical vapor deposition (CVD).

18. The process of claim 15 wherein the providing the carbon scaffold step comprises:
providing a molten carbonate;
dissociating the molten carbonate into a plurality of carbonate ions;
electrocatalytically reducing the carbonate ions to produce a graphitic carbon material comprised of a plurality of carbon particles.

19. The process of claim 15 further comprising using the material as an anode in a lithium-ion battery.

20. The process of claim 15 wherein the depositing step comprises initially deriving the silicon nanoparticles from monosilane or trichlorosilane.
